(19) United States
(12) Patent Application Publication
(10) Pub. No.: US 2025/0248018 A1
(43) Pub. Date: Jul. 31, 2025

(54) MULTI-BIT DEVICE, LAYOUT, AND METHOD

(71) Applicant: TAIWAN SEMICONDUCTOR MANUFACTURING COMPANY, LTD., Hsinchu (TW)

(72) Inventors: Chen-Ling WU, Hsinchu (TW); Chih-Liang CHEN, Hsinchu (TW); Chi-Yu LU, Hsinchu (TW); Ya-Chi CHOU, Hsinchu (TW); Johnny Chiahao LI, Hsinchu (TW)

(21) Appl. No.: 18/742,353

(22) Filed: Jun. 13, 2024

Related U.S. Application Data
(60) Provisional application No. 63/626,170, filed on Jan. 29, 2024.

(51) Int. Cl. H10B 10/00

(52) U.S. Cl. CPC H10B 10/12

(57) ABSTRACT

An IC device includes first and second bit circuits adjacent to each other along a row direction, third and fourth bit circuits adjacent to each other along the row direction, and a first column of output pins aligned in a column direction. The first and second bit circuits include first through fourth power rails and first through sixth active areas extending in the row direction, and the third and fourth bit circuits include the fourth power rail, fifth through seventh power rails, and seventh through twelfth active areas extending in the row direction. The first column of output pins includes first and second output pins adjacent to the second bit circuit and coupled to the respective first and second bit circuits and third and fourth output pins adjacent to the fourth bit circuit and coupled to the respective third and fourth bit circuits.

### PRIORITY CLAIM

The present application claims the priority of U.S. Provisional Application No. 63/626,170, filed Jan. 29, 2024, which is incorporated herein by reference in its entirety.

### BACKGROUND

In many applications, integrated circuits (ICs) include logic, processor, computational, or other circuits in which multiple data bits are handled simultaneously. Multi-bit circuits include multi-bit flip-flop devices that include multiple single-bit flip-flops, each of which can store a single bit of data, with one of two states representing “one” and the other “zero.” Such data storage can be used for storage of state, and such a circuit can be described as sequential logic in electronics. D-type flip-flops are widely used as the basic building blocks of random-access memory (RAM) and registers. The D-type flip-flop captures the D-input value at a specified edge (i.e., rising or falling) of a clock signal. After the rising/falling clock signal edge, the captured value is available at an output terminal, e.g., a signal pin.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are plan views, and FIG. 1C is a side view, of a multi-bit device and layout, in accordance with some embodiments.

FIGS. 2A and 2B are plan views, and FIG. 2C is a side view, of a multi-bit device and layout, in accordance with some embodiments.

FIG. 3 is a schematic diagram of a multi-bit flip-flop circuit, in accordance with some embodiments.

FIG. 4 is a flowchart of a method of manufacturing an IC device, in accordance with some embodiments.

FIG. 5 is a flowchart of a method of generating an IC layout diagram, in accordance with some embodiments.

FIG. 6 is a block diagram of an IC layout diagram generation system, in accordance with some embodiments.

FIG. 7 is a block diagram of an IC manufacturing system, and an IC manufacturing flow associated therewith, in accordance with some embodiments.

### DETAILED DESCRIPTION

The following disclosure provides many different embodiments, or examples, for implementing different features of the provided subject matter. Specific examples of components, values, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In various embodiments, an integrated circuit (IC) device and corresponding layout diagram and manufacturing method include bit circuits arranged in rows adjacent to one or more columns of output pins of the corresponding bit circuits. In some embodiments, the IC device includes a multi-bit flip-flop circuit.

By aligning the output pins in columns and increasing row height from twice to three times a power rail pitch, a number of vertical metal segments can be reduced and a number of placement choices for horizontal metal segments increased compared to other approaches, e.g., those without output pins aligned in columns and including row heights of twice a power rail pitch. The increased number of placement choices allows horizontal metal segments to be spaced farther apart than those in such other approaches, thereby lowering capacitance and enabling power reduction, e.g., of one or more clock signals, by approximately 5 or 6 percent in some embodiments.

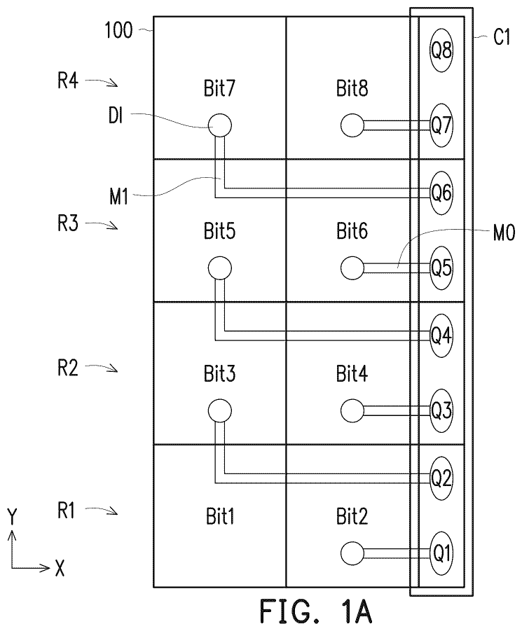

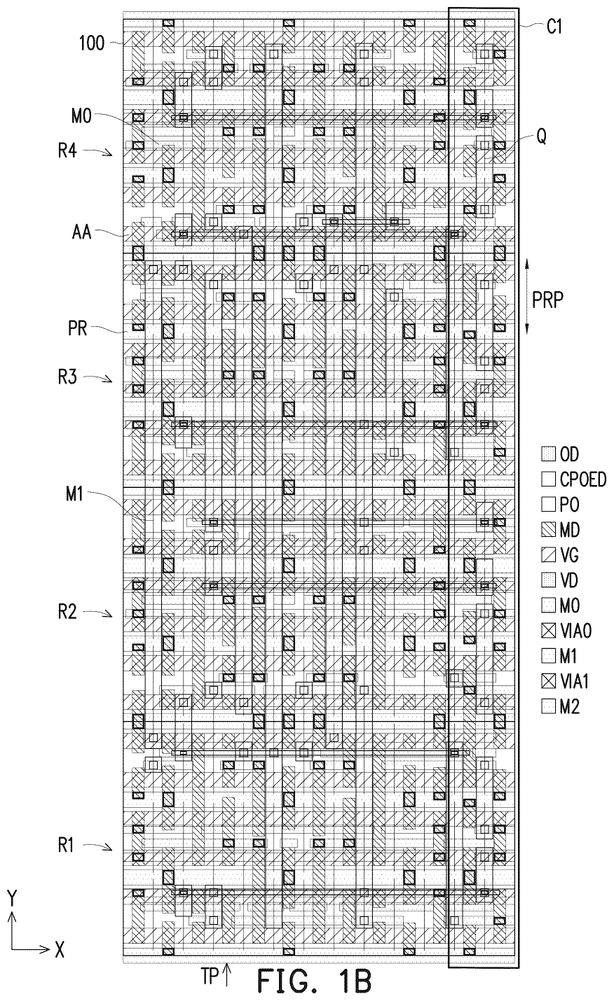

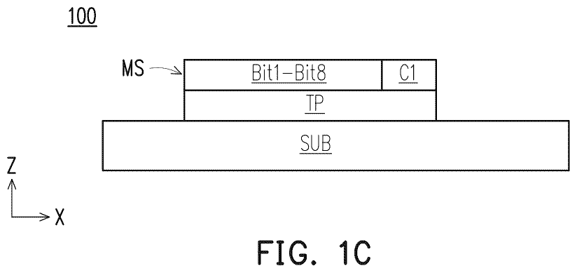

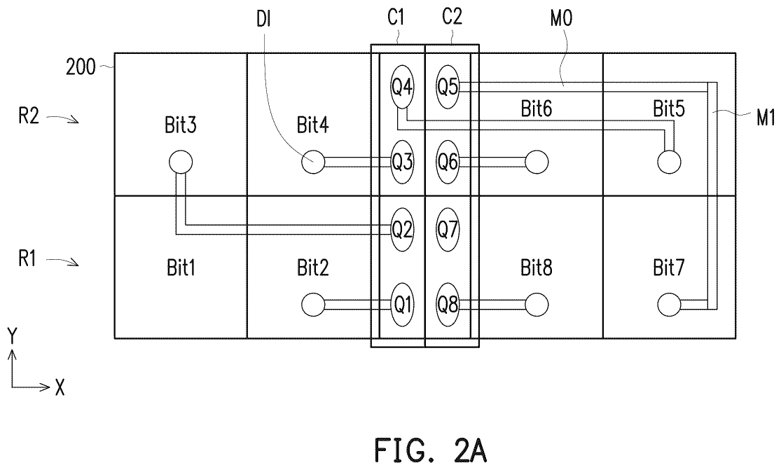

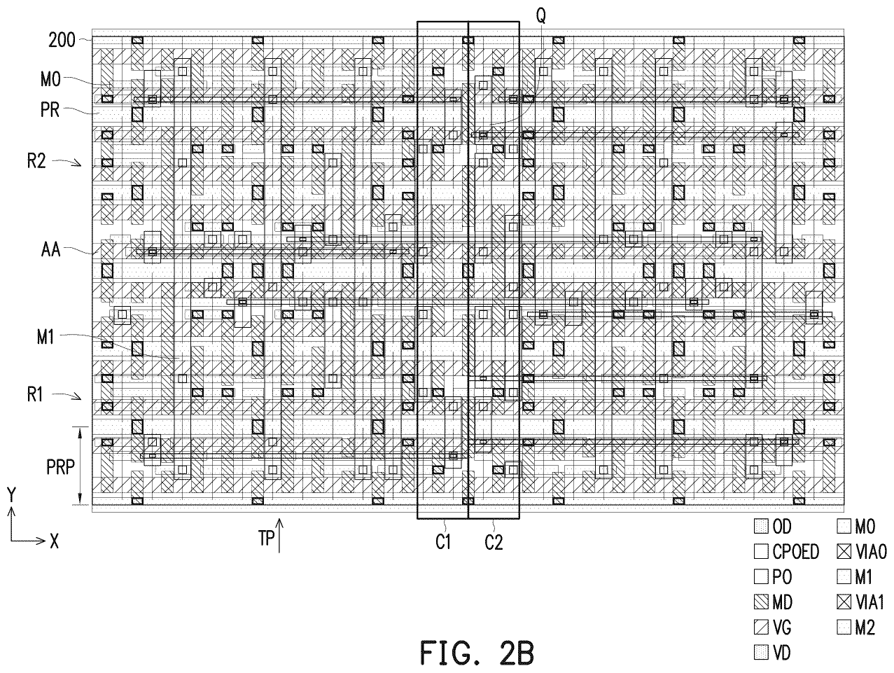

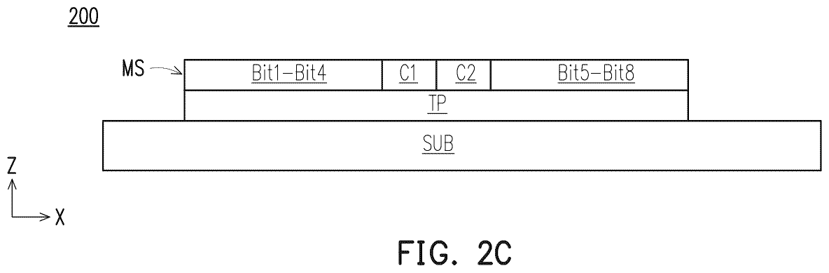

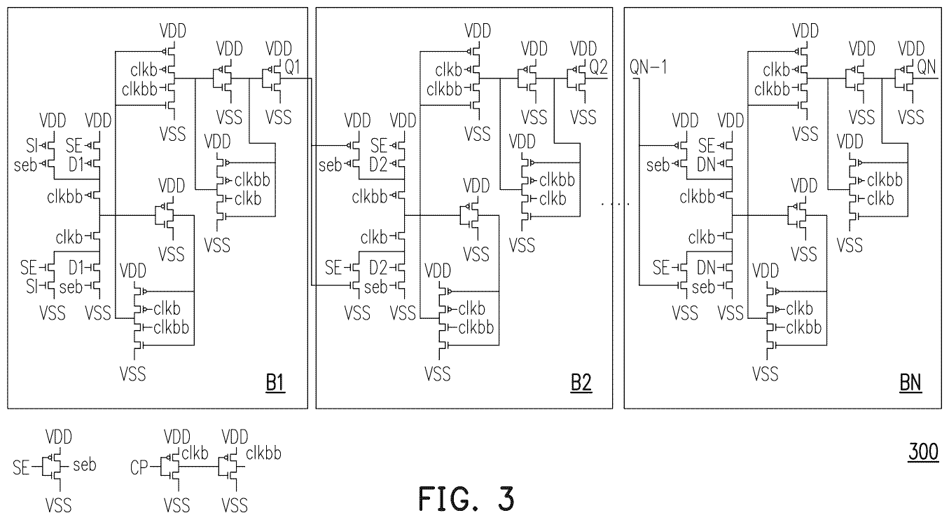

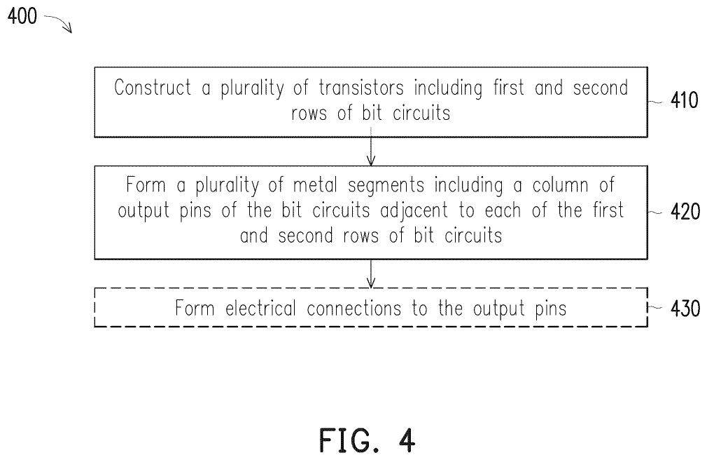

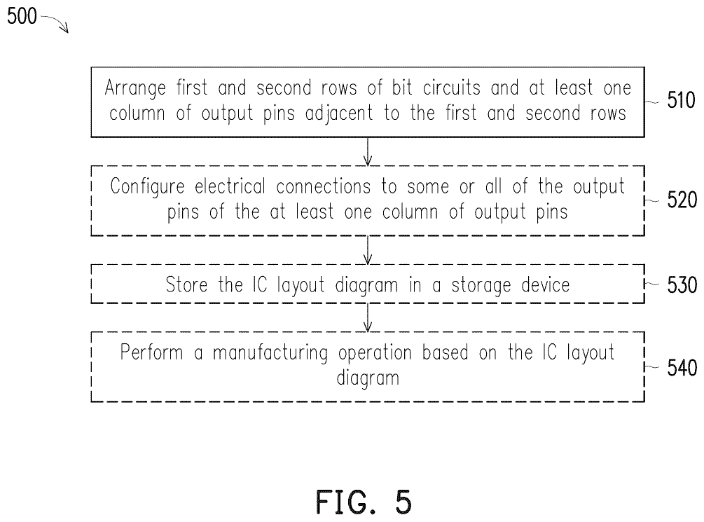

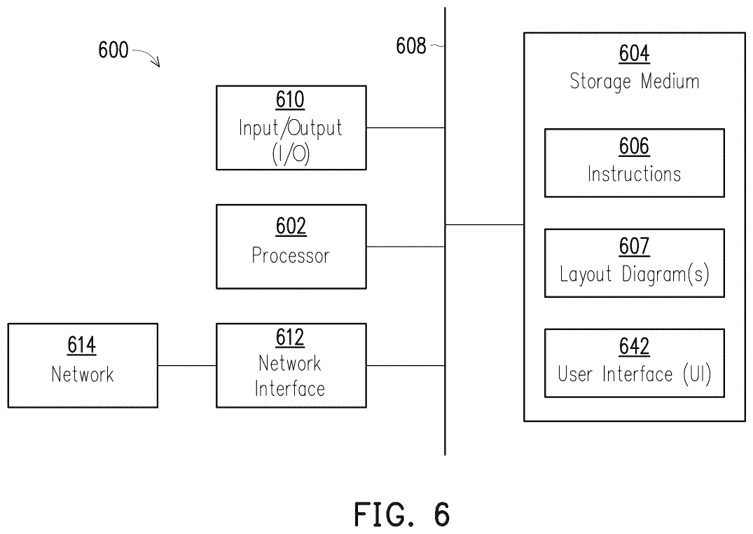

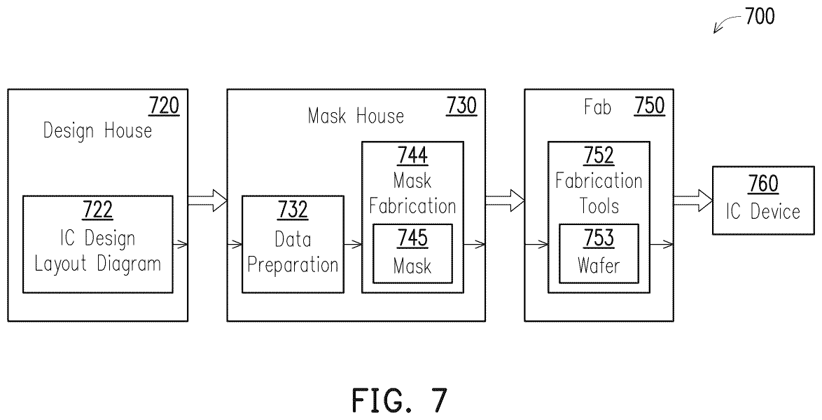

In accordance with various embodiments, FIGS. 1A-1C are views of a multi-bit IC device and layout diagram 100, FIGS. 2A-2C are views of a multi-bit IC device and layout diagram 200, FIG. 3 is a schematic diagram of a multi-bit flip-flop circuit 300 usable as multi-bit IC device 100 or 200, FIG. 4 is a flowchart of a method 400 of manufacturing a multi-bit IC device based on a corresponding one or more of IC layout diagrams 100 or 200, FIG. 5 is a flowchart of a method 500 of generating one or more of IC layout diagrams 100 or 200, e.g., using a system 600 discussed below with respect to FIG. 6 and, e.g., in accordance with an IC manufacturing flow associated with an IC manufacturing system 700 discussed below with respect to FIG. 7.

Each of the figures herein, e.g., FIGS. 1A-2C, is simplified for the purpose of illustration. The figures are views of IC structures, devices, and layout diagrams with various features included and excluded to facilitate the discussion below. In various embodiments, an IC structure, device and/or layout diagram includes one or more features corresponding to power distribution structures, metal interconnects, contacts, vias, gate structures, source/drain (S/D) structures, bulk connections, or other transistor elements, isolation structures, or the like, in addition to the features depicted in FIGS. 1A-2C.

In each of IC devices/layout diagrams 100 and 200, reference designators represent both IC device features and the IC layout features used to at least partially define the corresponding IC device features in a manufacturing process, e.g., method 400 discussed below with respect to FIG. 4 and/or the IC manufacturing flow associated with IC manufacturing system 700 discussed below with respect to FIG. 7. Accordingly, each of IC devices/layout diagrams 100 and 200 represents a view of both an IC layout diagram 100 or 200 and a corresponding IC device 100 or 200.

FIGS. 1A and 1B depict plan views of multi-bit IC device/layout diagram 100, X and Y directions, and a key corresponding to the features discussed below, in accordance with some embodiments. FIG. 1A is a high-level depiction of multi-bit IC device/layout diagram 100, and FIG. 1B is a more detailed depiction of a non-limiting example of multi-bit IC device/layout diagram 100. FIG. 1C depicts a side view of multi-bit IC device/layout diagram 100, the X direction, and a Z direction, in accordance with some embodiments.

Multi-bit IC device/layout diagram 100, also referred to as IC device/layout diagram 100 or IC 100 in some embodiments, includes four rows R1-R4 of bit circuits Bit1-Bit8 aligned in the X direction, and a column C1 of output pins Q1-Q8 aligned in the Y direction. Row R1 includes bit circuits Bit1 and Bit2 and output pins Q1 and Q2, row R2 includes bit circuits Bit3 and Bit4 and output pins Q3 and Q4, row R3 includes bit circuits Bit5 and Bit6 and output pins Q5 and Q6, and row R4 includes bit circuits Bit7 and Bit8 and output pins Q7 and Q8, each discussed below.

FIGS. 2A and 2B depict plan views of multi-bit IC device/layout diagram 200, the X and Y directions, and the key, in accordance with some embodiments. FIG. 2A is a high-level depiction of multi-bit IC device/layout diagram 200, and FIG. 2B is a more detailed depiction of a non-limiting example of multi-bit IC device/layout diagram 200. FIG. 2C depicts a side view of multi-bit IC device/layout diagram 200 and the X and Z directions, in accordance with some embodiments.

Multi-bit IC device/layout diagram 200, also referred to as IC device/layout diagram 200 or IC 200 in some embodiments, includes two rows R1-R2 of bit circuits Bit1-Bit8 aligned in the X direction, column C1 of output pins Q1-Q4 aligned in the Y direction, and a column C2 of output pins Q5-Q8 aligned in the Y direction. In IC device 200, row R1 includes bit circuits Bit1, Bit2, Bit7, and Bit8 and output pins Q1, Q2, Q7, and Q8, and row R2 includes bit circuits Bit3-Bit6 and output pins Q3-Q6.

The numbers of rows, bit circuits, and output pins depicted in FIGS. 1A-2C are non-limiting examples provided for the purpose of illustration. IC device/layout diagram 100 and/or 200 including numbers of rows, bit circuits, and/or output pins other than those depicted in FIGS. 1A-2C are within the scope of the present disclosure.

In the embodiments depicted in FIGS. 1A and 2A, output pin Q1 is coupled to bit circuit Bit2, output pin Q2 is coupled to bit circuit Bit3, output pin Q3 is coupled to bit circuit Bit4, output pin Q4 is coupled to bit circuit Bit5, output pin Q5 is coupled to bit circuit Bit6, output pin Q6 is coupled to bit circuit Bit7, and output pins Q7 and Q8 are coupled to bit circuit Bit8. Output pin/bit circuit configurations other than those depicted in FIGS. 1A and 2A are within the scope of the present disclosure.

Two or more circuit elements are considered to be coupled based on one or more direct signal connections and/or one or more indirect signal connections that include one or more logic devices, e.g., an inverter or logic gate, between the two or more circuit elements. In some embodiments, signal communications between the two or more coupled circuit elements are capable of being modified, e.g., inverted or made conditional, by the one or more logic devices.

In the embodiments depicted in FIGS. 1A and 2A, each of bit circuits Bit2-Bit8 includes an input pin DI (a single instance labeled for clarity), also referred to as a data input pin DI or signal input pin DI in some embodiments. Each input pin DI is coupled to a corresponding output pin Q1-Q7 through a vertical metal region/segment M1 and a horizontal metal region/segment M0 (single instances labeled for clarity). Input/output pin configurations other than those depicted in FIGS. 1A and 2A are within the scope of the present disclosure.

As depicted in FIGS. 1B and 2B, each row R1-R4 corresponds to a total of four power rails PR (a single instance labeled for clarity) extending in the X direction and spaced apart in the Y direction by a power rail pitch PRP. Each row R1-R4 thereby corresponds to three times pitch PRP with adjacent ones of rows R1-R4 sharing corresponding instances of power rail PR.

As depicted in FIGS. 1B and 2B, the instances of metal regions/segments M0 are positioned in accordance with a total of three first metal tracks (not labeled) extending between adjacent instances of power rail PR.

As depicted in FIGS. 1B and 2B, column C1 and column C2, if present, include instances of output pins Q1-Q8 (a representative instance labeled as output pin Q) including vertical metal regions/segments. In the embodiments depicted in FIGS. 1B and 2B, the instances of output pin Q overlie and are aligned along single instances of gate region/structure (not labeled) and are thereby considered to be aligned in the Y direction. In some embodiments, instances of output pin Q are otherwise positioned, e.g., overlying adjacent instances of a gate region/structure or being between adjacent instances of a gate region/structure, and are thereby considered to be aligned in the Y direction.

In some embodiments, each metal region/segment M0 and power rail PR is a metal region/segment of a first metal layer, also referred to as a metal zero layer in some embodiments, of a design and manufacturing process used to manufacture IC device 100 or 200 based on IC layout diagram 100 or 200, and each input pin DI, output pin Q, and metal region/segment M1 is a metal region/segment of a second metal layer, also referred to as a metal one layer in some embodiments, as further discussed below.

A bit circuit, e.g., bit circuit Bit1-Bit8, is a logic, latch, flip-flop, or other circuit configured to operate on a single data bit by including some or all of a plurality of p-type and n-type transistors, e.g., a plurality of transistors TP, arranged accordingly.

As depicted in FIGS. 2B and 3B, plurality of transistors TP includes active regions/areas AA (a single instance labeled for clarity) extending in the X direction. Each row R1-R4 includes a total of six instances of active region/area AA.

In some embodiments, alternating instances of power rail PR are configured to have either a power supply voltage VDD or a power supply reference voltage VSS, and the adjacent instances of active region/area AA have corresponding p-type or n-type doping accordingly.

Plurality of transistors TP also includes additional features, e.g., metal-like defined regions/segments MD, gate regions/structures PO, dummy gate regions/structures CPODE, via regions structures VG and VD included in the key depicted in FIGS. 1B and 2B, that are not labeled for the purpose of clarity.

As depicted in FIGS. 1C and 2C, plurality of transistors TP is positioned on a substrate SUB, and a plurality of metal regions/segments MS is positioned on plurality of transistors TP. Plurality of metal regions/segments MS includes power rails PR, input pins DI, and metal regions/segments M0 and M1 of bit circuits Bit1-Bit8 and output pins Q1-Q8 arranged as depicted in each of FIGS. 1C and 2C.

In some embodiments, plurality of metal regions/segments MS also includes instances of metal regions/segments and/or via regions/structures in addition to those discussed above, e.g., metal regions/segments M2 and via regions/structures VIA0 and VIA1 included in the key depicted in FIGS. 1B and 2B, that are not labeled for the purpose of clarity.

In some embodiments, plurality of regions/metal segments MS includes the regions/segments arranged as a plurality of signal paths, e.g., one or more clock signal paths, in accordance with the arrangement of plurality of transistors TP.

An active region/area, e.g., active region/area AA, is a region in an IC layout diagram included in a manufacturing process as part of defining an active area, also referred to as an oxide diffusion or definition (OD), in a semiconductor substrate, e.g., substrate SUB, either directly or in an n-well or p-well region/area (not shown for the purpose of clarity), in which one or more IC device features, e.g., a S/D structure, is formed. In some embodiments, an active area is an n-type or p-type active area of a planar transistor, a FinFET, or a GAA transistor. In various embodiments, an active area (structure) includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material.

In some embodiments, an active area is a region in an IC layout diagram included in the manufacturing process as part of defining a nano-sheet structure, e.g., a continuous volume of one or more layers of one or more semiconductor materials having either n-type or p-type doping. In various embodiments, individual nano-sheet layers include a single monolayer or multiple monolayers of a given semiconductor material.

A S/D region/structure is a region in the IC layout diagram included in the manufacturing process as part of defining a S/D structure, also referred to as a semiconductor structure in some embodiments, configured to have a doping type opposite that of the corresponding active region/area. In some embodiments, a S/D region/structure is configured to have lower resistivity than an adjacent channel feature, e.g., a portion of the corresponding active region/area of a planar FET, a fin structure of a FinFET, or a gate structure of a GAA transistor. In some embodiments, a S/D region/structure includes one or more portions having doping concentrations greater than one or more doping concentrations present in the corresponding channel feature. In some embodiments, an S/D region/structure includes epitaxial regions of a semiconductor material, e.g., Si, SiGe, and/or silicon-carbide SiC.

An MD region/segment is a conductive region in the IC layout diagram included in the manufacturing process as part of defining an MD segment, also referred to as a conductive segment or MD conductive line or trace, in and/or on the semiconductor substrate. In some embodiments, an MD segment includes a portion of at least one metal layer, e.g., a contact layer, overlying and contacting the substrate and having a thickness sufficiently small to enable formation of an insulation layer between the MD segment and an overlying metal layer, e.g., the first metal layer. In various embodiments, an MD segment includes one or more of copper (Cu), silver (Ag), tungsten (W), titanium (Ti), nickel (Ni), tin (Sn), aluminum (Al) or another metal or material suitable for providing a low resistance electrical connection between IC structure elements, i.e., a resistance level below a predetermined threshold corresponding to one or more tolerance levels of a resistance-based effect on circuit performance.

In various embodiments, an MD segment includes a section of the semiconductor substrate and/or an epitaxial layer having a doping level, e.g., based on an implantation process, sufficient to cause the segment to have the low resistance level. In various embodiments, a doped MD segment includes one or more dopant materials having doping concentrations of about 1*10¹⁶ per cubic centimeter or greater.

In some embodiments, a manufacturing process includes two MD layers, and an MD region/segment, e.g., MD region/segment MD, refers to both of the two MD layers in the manufacturing process.

A gate region/structure is a region in the IC layout diagram included in the manufacturing process as part of defining a gate structure. A gate structure is a volume including one or more conductive segments, e.g., a gate electrode, including one or more conductive materials, e.g., polysilicon, copper (Cu), aluminum (Al), tungsten (W), cobalt (Co), ruthenium (Ru), or one or more other metals or other suitable materials, substantially surrounded by one or more insulating materials, the one or more conductive segments thereby being configured to control a voltage provided to an adjacent gate dielectric layer.

A gate dielectric layer is a volume including one or more insulating materials, e.g., silicon dioxide, silicon nitride (Si₃N₄), and/or one or more other suitable material such as a low-k material having a k value less than 3.8 or a high-k material having a k value greater than 3.8 or 7.0 such as aluminum oxide (Al₂O₃), hafnium oxide (HfO₂), tantalum pentoxide (Ta₂O₅), or titanium oxide (TiO₂), suitable for providing a high electrical resistance between IC structure elements, i.e., a resistance level above a predetermined threshold corresponding to one or more tolerance levels of a resistance-based effect on circuit performance.

A metal line or region, e.g., power rail PR, input pin DI, output pin Q, or metal region M0 or M1, is a region in the IC layout diagram included in the manufacturing process as part of defining a metal line structure including one or more conductive materials, e.g., polysilicon, copper (Cu), aluminum (Al), tungsten (W), cobalt (Co), ruthenium (Ru), or one or more other metals or other suitable materials, in a given metal layer of the manufacturing process. In various embodiments, a metal region/segment corresponds to a first metal layer (also referred to as a metal zero layer M0 in some embodiments), or a second or higher level metal layer, e.g., metal layer M1, of the manufacturing process.

A via region/structure is a region in the IC layout diagram included in the manufacturing process as part of defining a via structure including one or more conductive materials configured to provide an electrical connection between an overlying conductive structure and an underlying conductive structure.

By the configurations discussed above, each of multi-bit IC device/layout diagram 100 and 200 includes bit circuits Bit1-Bit8 arranged in rows R1-R4 adjacent to one or more columns C1/C2 of output pins Q1-Q8 of bit circuits Bit1-Bit8. By including output pins Q1-Q8 aligned in columns and rows R1-R4 having a height of three times power rail pitch PRP, a number of vertical metal segments M1 can be reduced and a number of placement choices for horizontal metal segments M0 increased compared to other approaches, e.g., those without output pins aligned in columns and including row heights of twice a power rail pitch. The increased number of placement choices allows horizontal metal segments M0 of IC device/layout diagram 100 and 200 to be spaced farther apart than those in such other approaches, thereby lowering capacitance and enabling power reduction.

FIG. 3 is a schematic diagram of multi-bit flip-flop circuit 300 usable as IC layout/device 100 or 200 in accordance with some embodiments. In some embodiments, multi-bit flip-flop circuit 300 is referred to as multi-bit flip-flop IC 300, multi-bit D-flip-flop circuit 300, D-flip-flop circuit 300, flip-flop 300, or D-flip-flop 300.

Flip-flop 300 includes a non-limiting example of plurality of transistors TP discussed above arranged in accordance with a multi-bit flip-flop circuit in which individual transistors are not labeled for the purpose of clarity.

Flip-flop 300 includes an inverter (not labeled) configured to receive a select signal SE and output an inverted select signal seb, and a pair of inverters (not labeled) configured to receive to receive a clock signal CP and output a complementary pair of clock signals clkb and clkbb.

Flip-flop 300 also includes a plurality of N single-bit flip-flop circuits B1-BN, also referred to as bit circuits B1-BN in some embodiments, usable as corresponding ones of bit circuits Bit1-Bit8 discussed above with respect to FIGS. 1A-2C.

Each bit circuit B1-BN includes p-type and n-type transistors configured to receive select signals SE and seb, clock signals clkb and clkbb, and a corresponding input data bit DI-DN, and is configured as depicted in FIG. 3 to, in operation, latch the corresponding input data bit DI-DN and output a corresponding output data bit Q1-QN responsive to select signals SE and seb and clock signals clkb and clkbb.

One of IC devices/layout diagrams 100 or 200 corresponding to flip-flop 300 is thereby capable of performing a multi-bit operation in accordance with the benefits discussed above with respect to IC devices/layout diagrams 100 or 200.

FIG. 4 is a flowchart of method 400 of manufacturing a multi-bit IC device, in accordance with some embodiments. Method 400 is operable to form IC device 100 or 200 discussed above with respect to FIGS. 1A-3.

In some embodiments, the operations of method 400 are performed in the order depicted in FIG. 4. In some embodiments, the operations of method 400 are performed in an order other than the order of FIG. 4. In some embodiments, one or more additional operations are performed before, during, between, and/or after the operations of method 400.

In some embodiments, one or more operations of method 400 are a subset of operations of a method of forming an IC and/or IC package including one or more multi-bit IC devices.

At operation 410, a plurality of transistors including first and second rows of bit circuits is constructed on a semiconductor substrate. Constructing the plurality of transistors including first and second rows of bit circuits includes constructing plurality of transistors TP including two or more of rows R1-R4 on substrate SUB discussed above with respect to FIGS. 1A-2C.

In some embodiments, constructing the plurality of transistors includes arranging the plurality of transistors in accordance with flip-flop circuit 300 discussed above with respect to FIG. 3.

Constructing the plurality of transistors includes forming one or more structures and/or devices, e.g., transistor features including MD segments and/or S/D structures in active areas of the semiconductor substrate, gate structures on and/or in the active areas, and electrical connections between the devices in accordance with an IC design.

Constructing the plurality of transistors includes performing a first plurality of manufacturing operations, e.g., one or more of a lithography, diffusion, deposition, etching, planarizing, or other operation suitable for building a resistive, magnetic, or other material layer, a dielectric layer, and/or a gate structure adjacent to S/D structures and overlying or otherwise being proximate to an active area of the semiconductor substrate.

At operation 420, a plurality of metal segments including a column of output pins of the bit circuits is formed adjacent to each of the first and second rows of bit circuits. Forming the plurality of metal segments includes forming the plurality of metal segments on the plurality of transistors.

Forming the plurality of metal segments including the column of output pins of the bit circuits includes forming plurality of metal segments MS including power rails PR, metal segments M0 and M1, input pins DI, and some or all of column C1 and/or C2 of output pins Q1-Q8 of bit circuits Bit1-Bit8 discussed above with respect to FIGS. 1A-2C.

In some embodiments, forming the plurality of metal segments includes forming the plurality of metal segments in accordance with flip-flop circuit 300 discussed above with respect to FIG. 3.

In some embodiments, forming the plurality of metal segments includes performing one or more front end of line (FEOL) and/or back end of line (BEOL) operations including performing a second plurality of manufacturing operations, e.g., one or more of a lithography, diffusion, deposition, etching, planarizing, or other operation suitable for building metal segments, conductive, resistive or other material layers, and/or dielectric layers and overlying the plurality of transistors.

At operation 430, in some embodiments, electrical connections to the output pins of the bit circuits are formed. Forming the electrical connections includes forming electrical connections to some or all of output pins Q1-Q8 discussed above with respect to FIGS. 1A-3.

In some embodiments, forming the electrical connections includes forming some of plurality of metal segments MS discussed above with respect to FIGS. 1A-3.

Forming the electrical connections includes performing one or more etching and deposition processes by which one or more metal lines are configured in accordance with one or more masks. Performing a deposition process includes depositing one or more conductive materials, e.g., one or more of Cu, Ag, W, Ti, Ni, Sn, Al or another metal or suitable material, e.g., polysilicon.

By performing some or all of the operations of method 400, an IC device is manufactured including a multi-bit IC device including bit circuits arranged in rows adjacent to one or more columns of output pins of the corresponding bit circuits, thereby enabling the benefits discussed above with respect to multi-bit IC devices 100 and 200.

FIG. 5 is a flowchart of method 500 of generating an IC layout diagram, e.g., one or more of IC layout diagrams 100 or 200 discussed above with respect to FIGS. 1A-3, in accordance with some embodiments.

In some embodiments, generating the IC layout diagram includes generating the IC layout diagram corresponding to an IC device, e.g., IC device 100 or 200 discussed above with respect to FIGS. 1A-3, manufactured based on the generated IC layout diagram.

In some embodiments, some or all of method 500 is executed by a processor of a computer, e.g., a processor 602 of IC layout diagram generation system 600, discussed below with respect to FIG. 6.

Some or all of the operations of method 500 are capable of being performed as part of a design procedure performed in a design house, e.g., a design house 720 discussed below with respect to FIG. 7.

In some embodiments, the operations of method 500 are performed in the order depicted in FIG. 5. In some embodiments, the operations of method 500 are performed simultaneously and/or in an order other than the order depicted in FIG. 5. In some embodiments, one or more operations are performed before, between, during, and/or after performing one or more operations of method 500.

At operation 510, first and second rows of bit circuits are arranged and at least one column of output pins is arranged adjacent to the first and second rows of bit circuits. Arranging the first and second rows of bit circuits and at least one column of output pins includes arranging two or more of rows R1-R4 and some or all of columns C1 and/or C2 of output pins Q1-Q8 discussed above with respect to FIGS. 1A-2C.

Arranging the first and second rows of bit circuits and at least one column of output pins includes arranging plurality of transistors TP and plurality of metal regions MS discussed above with respect to FIGS. 1A-2C.

In some embodiments, arranging the first and second rows of bit circuits and at least one column of output pins includes arranging the first and second rows of bit circuits and at least one column of output pins in accordance with flip-flop circuit 300 discussed above with respect to FIG. 3.

At operation 520, in some embodiments, electrical connections to some or all of the output pins of the at least one column of output pins are configured in the IC layout diagram. In some embodiments, configuring the electrical connections to the some or all of the output pins includes configuring one or more metal regions of plurality of metal regions MS discussed above with respect to FIGS. 1A-2C.

In some embodiments, configuring the electrical connections to some or all of the output pins is part of arranging an IC device including the multi-bit IC device.

At operation 530, in some embodiments, the IC layout diagram including the first and second rows of bit circuits and at least one column of output pins is stored in a storage device. In some embodiments, storing the IC layout diagram in the storage device includes storing one or more of IC layout diagrams 100 or 200 discussed above with respect to FIGS. 1A-2C, in the storage device.

In various embodiments, storing the IC layout diagram in the storage device includes storing the IC layout diagram in a non-volatile, computer-readable memory or a cell library, e.g., a database, and/or includes storing the IC layout diagram over a network. In some embodiments, storing the IC layout diagram in the storage device includes storing the IC layout diagram in a cell library, in layout diagrams 609, and/or over network 614 of IC layout diagram generation system 600 discussed below with respect to FIG. 6.

At operation 540, in some embodiments, one or more manufacturing operations are performed based on the IC layout diagram. In some embodiments, performing one or more manufacturing operations includes performing one or more lithographic exposures based on the IC layout diagram. Performing one or more manufacturing operations, e.g., one or more lithographic exposures, based on the IC layout diagram is discussed above with respect to FIG. 4 and below with respect to FIG. 7.

By executing some or all of the operations of method 600, an IC layout diagram is generated corresponding to a multi-bit IC device including bit circuits arranged in rows adjacent to one or more columns of output pins of the corresponding bit circuits, thereby enabling the benefits discussed above with respect to multi-bit IC devices 100 and 200.

FIG. 6 is a block diagram of IC layout diagram generation system 600, in accordance with some embodiments. Methods described herein of designing IC layout diagrams in accordance with one or more embodiments are implementable, for example, using IC layout diagram generation system 600, in accordance with some embodiments.

In some embodiments, IC layout diagram generation system 600 is a general purpose computing device including a hardware processor 602 and a non-transitory, computer-readable storage medium 604. Storage medium 604, amongst other things, is encoded with, i.e., stores, computer program code 606, i.e., a set of executable instructions. Execution of instructions 606 by hardware processor 602 represents (at least in part) an electronic design automation (EDA) tool which implements a portion or all of a method, e.g., method 500 of generating an IC layout diagram described above with respect to FIG. 5 (hereinafter, the noted processes and/or methods).

Processor 602 is electrically coupled to computer-readable storage medium 604 via a bus 608. Processor 602 is also electrically coupled to an I/O interface 610 by bus 608. A network interface 612 is also electrically connected to processor 602 via bus 608. Network interface 612 is connected to a network 614, so that processor 602 and computer-readable storage medium 604 are capable of connecting to external elements via network 614. Processor 602 is configured to execute computer program code 606 encoded in computer-readable storage medium 604 in order to cause IC layout diagram generation system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, computer-readable storage medium 604 is an electronic, magnetic, optical, electromagnetic, infrared, and/or a semiconductor system (or apparatus or device). For example, computer-readable storage medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable storage medium 604 includes a compact disk-read only memory (CD-ROM), a compact disk-read/write (CD-R/W), and/or a digital video disc (DVD).

In one or more embodiments, computer-readable storage medium 604 stores computer program code 606 configured to cause IC layout diagram generation system 600 (where such execution represents (at least in part) the EDA tool) to be usable for performing a portion or all of the noted processes and/or methods. In one or more embodiments, computer-readable storage medium 604 also stores information which facilitates performing a portion or all of the noted processes and/or methods.

In one or more embodiments, computer-readable storage medium 604 stores IC layout diagrams 607 of IC layout diagrams including such IC layout diagrams as disclosed herein, e.g., IC layout diagrams 100 and 200 discussed above with respect to FIGS. 1A-5.

IC layout diagram generation system 600 includes I/O interface 610. I/O interface 610 is coupled to external circuitry. In one or more embodiments, I/O interface 610 includes a keyboard, keypad, mouse, trackball, trackpad, touchscreen, and/or cursor direction keys for communicating information and commands to processor 602.

IC layout diagram generation system 600 also includes network interface 612 coupled to processor 602. Network interface 612 allows system 600 to communicate with network 614, to which one or more other computer systems are connected. Network interface 612 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more IC layout diagram generation systems 600.

IC layout diagram generation system 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. IC layout diagram generation system 600 is configured to receive information related to a UI through I/O interface 610. The information is stored in computer-readable medium 604 as user interface (UI) 642.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by IC layout diagram generation system 600. In some embodiments, a layout diagram which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

FIG. 7 is a block diagram of IC manufacturing system 700, and an IC manufacturing flow associated therewith, in accordance with some embodiments. In some embodiments, based on an IC layout diagram, at least one of (A) one or more semiconductor masks or (B) at least one component in a layer of a semiconductor integrated circuit is fabricated using manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout diagram 722. IC design layout diagram 722 includes various geometrical patterns, e.g., one or more of IC layout diagrams 100 or 200 discussed above with respect to FIGS. 1A-6. The geometrical patterns correspond to patterns of metal, oxide, or semiconductor layers that make up the various components of IC device 760 to be fabricated. The various layers combine to form various IC features. For example, a portion of IC design layout diagram 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout diagram 722. The design procedure includes one or more of logic design, physical design or place and route. IC design layout diagram 722 is presented in one or more data files having information of the geometrical patterns. For example, IC design layout diagram 722 can be expressed in a GDSII file format or DFII file format.

Mask house 730 includes data preparation 732 and mask fabrication 744. Mask house 730 uses IC design layout diagram 722 to manufacture one or more masks 745 to be used for fabricating the various layers of IC device 760 according to IC design layout diagram 722. Mask house 730 performs mask data preparation 732, where IC design layout diagram 722 is translated into a representative data file (RDF). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The design layout diagram 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout diagram 722. In some embodiments, mask data preparation 732 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout diagram 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout diagram 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout diagram 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout diagram 722.

It should be understood that the above description of mask data preparation 732 has been simplified for the purposes of clarity. In some embodiments, data preparation 732 includes additional features such as a logic operation (LOP) to modify the IC design layout diagram 722 according to manufacturing rules. Additionally, the processes applied to IC design layout diagram 722 during data preparation 732 may be executed in a variety of different orders.

After mask data preparation 732 and during mask fabrication 744, a mask 745 or a group of masks 745 are fabricated based on the modified IC design layout diagram 722. In some embodiments, mask fabrication 744 includes performing one or more lithographic exposures based on IC design layout diagram 722. In some embodiments, an electron-beam (e-beam) or a mechanism of multiple e-beams is used to form a pattern on a mask (photomask or reticle) 745 based on the modified IC design layout diagram 722. Mask 745 can be formed in various technologies. In some embodiments, mask 745 is formed using binary technology. In some embodiments, a mask pattern includes opaque regions and transparent regions. A radiation beam, such as an ultraviolet (UV) or EUV beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask. In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC fab 750 is an IC fabrication business that includes one or more manufacturing facilities for the fabrication of a variety of different IC products. In some embodiments, IC Fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 750 includes wafer fabrication tools 752 configured to execute various manufacturing operations on semiconductor wafer 753 such that IC device 760 is fabricated in accordance with the mask(s), e.g., mask 745. In various embodiments, fabrication tools 752 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 750 uses mask(s) 745 fabricated by mask house 730 to fabricate IC device 760. Thus, IC fab 750 at least indirectly uses IC design layout diagram 722 to fabricate IC device 760. In some embodiments, semiconductor wafer 753 is fabricated by IC fab 750 using mask(s) 745 to form IC device 760. In some embodiments, the IC fabrication includes performing one or more lithographic exposures based at least indirectly on IC design layout diagram 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

In some embodiments, an IC device includes first and second bit circuits adjacent to each other along a row direction, third and fourth bit circuits adjacent to each other along the row direction, and a first column of output pins aligned in a column direction, wherein the first and second bit circuits include first through fourth power rails extending in the row direction and first through sixth active areas extending in the row direction, the third and fourth bit circuits include the fourth power rail and fifth through seventh power rails extending in the row direction and seventh through twelfth active areas extending in the row direction, and the first column of output pins includes first and second output pins adjacent to the second bit circuit and coupled to the respective first and second bit circuits and third and fourth output pins adjacent to the fourth bit circuit and coupled to the respective third and fourth bit circuits. In some embodiments, the first through seventh power rails are positioned in a first metal layer of the IC device, each of the first through fourth bit circuits includes a plurality of metal segments positioned in the first metal layer, and the metal segments of the plurality of metal segments are positioned in accordance with a total of three first metal tracks extending between adjacent power rails of the first through seventh power rails. In some embodiments, each of the first through fourth output pins includes a metal segment extending in the column direction in a second metal layer of the IC device. In some embodiments, each of the first through fourth bit circuits is coupled to a same clock signal path. In some embodiments, the IC device includes fifth and sixth bit circuits adjacent to each other along the row direction and seventh and eighth bit circuits adjacent to each other along the row direction, wherein the fifth and sixth bit circuits include the seventh power rail and eighth through tenth power rails extending in the row direction and thirteenth through eighteenth active areas extending in the row direction, the seventh and eighth bit circuits include the tenth power rail and eleventh through thirteenth power rails extending in the row direction and nineteenth through twenty-fourth active areas extending in the row direction, and the first column of output pins includes fifth and sixth output pins adjacent to the sixth bit circuit and coupled to the respective fifth and sixth bit circuits and seventh and eighth output pins adjacent to the eighth bit circuit and coupled to the respective seventh and eighth bit circuits. In some embodiments, the IC device includes a second column of output pins adjacent to the first column of output pins, fifth and sixth bit circuits adjacent to each other along the row direction, and seventh and eighth bit circuits adjacent to each other along the row direction, wherein the fifth and sixth bit circuits include the first through fourth power rails and first through sixth active areas, the seventh and eighth bit circuits include the fourth through seventh power rails and seventh through twelfth active areas, and the second column of output pins includes fifth and sixth output pins adjacent to the sixth bit circuit and coupled to the respective fifth and sixth bit circuits and seventh and eighth output pins adjacent to the eighth bit circuit and coupled to the respective seventh and eighth bit circuits. In some embodiments, the IC device includes a multi-bit flip-flop circuit and each of the first through fourth bit circuits includes a flip-flop bit circuit. In some embodiments, each of the first through fourth bit circuits includes an input pin.

In some embodiments, an IC device includes a first row including adjacent first and second flip-flop bits, a second row including adjacent third and fourth flip-flop bits, and a first column of output pins aligned perpendicular to the first and second rows, wherein the first and second flip-flop bits include first through fourth power rails and first through sixth active areas extending along the first row, the third and fourth flip-flop bits include the fourth power rail, fifth through seventh power rails, and seventh through twelfth active areas extending along the second row, and the first column of output pins includes a first output pin adjacent to the second flip-flop bit and electrically connected to the first flip-flop bit, a second output pin adjacent to the second flip-flop bit and electrically connected to the second flip-flop bit, a third output pin adjacent to the fourth flip-flop bit and electrically connected to the third flip-flop bit, and a fourth output pin adjacent to the fourth flip-flop bit and electrically connected to the fourth flip-flop bit. In some embodiments, the first through seventh power rails are positioned in a first metal layer of the IC device, each of the first through fourth flip-flop bits includes a plurality of metal segments positioned in the first metal layer, and the metal segments of the plurality of metal segments are positioned in accordance with a total of three first metal tracks extending between adjacent power rails of the first through seventh power rails. In some embodiments, each of the first through fourth output pins includes a metal segment extending perpendicular to the first and second rows in a second metal layer of the IC device. In some embodiments, the IC device includes a pair of clock paths electrically connected to each of the first through fourth bits. In some embodiments, the IC device includes a third row including adjacent fifth and sixth flip-flop bits and a fourth row including adjacent seventh and eighth flip-flop bits, wherein the fifth and sixth flip-flop bits include the seventh power rail, eighth through tenth power rails, and thirteenth through eighteenth active areas extending along the third row, the seventh and eighth flip-flop bits include the tenth power rail, eleventh through thirteenth power rails, and nineteenth through twenty-fourth active areas extending along the fourth row, and the first column of output pins includes a fifth output pin adjacent to the sixth flip-flop bit and electrically connected to the fifth flip-flop bit, a sixth output pin adjacent to the sixth flip-flop bit and electrically connected to the sixth flip-flop bit, a seventh output pin adjacent to the eighth flip-flop bit and electrically connected to the seventh flip-flop bit, and an eighth output pin adjacent to the eighth flip-flop bit and electrically connected to the eighth flip-flop bit. In some embodiments, the IC device includes a second column of output pins adjacent to the first column of output pins, wherein the first row includes adjacent fifth and sixth flip-flop bits, the second row includes adjacent seventh and eighth flip-flop bits, the fifth and sixth flip-flop bits include the first through fourth power rails and first through sixth active areas, the seventh and eighth flip-flop bits include the fourth through seventh power rails and seventh through twelfth active areas, and the second column of output pins includes a fifth output pin adjacent to the sixth flip-flop bit and electrically connected to the fifth flip-flop bit, a sixth output pin adjacent to the sixth flip-flop bit and electrically connected to the sixth flip-flop bit, a seventh output pin adjacent to the eighth flip-flop bit and electrically connected to the seventh flip-flop bit, and an eighth output pin adjacent to the eighth flip-flop bit and electrically connected to the eighth flip-flop bit. In some embodiments, each of the first through fourth flip-flop bits includes an input pin.

In some embodiments, a method of manufacturing an IC device includes constructing a plurality of transistors, constructing the plurality of transistors including forming first and second bit circuits including first through sixth active areas extending along a row direction and forming third and fourth bit circuits including seventh through twelfth active areas extending along the row direction, and forming a plurality of metal segments, forming the plurality of metal segments including forming first through seventh power rails extending in the row direction, wherein the first through third power rails overlie each of the first and second bit circuits, the fourth power rail overlies each of the first through fourth bit circuits, and the fifth through seventh power rails overlie each of the third and fourth bit circuits, and forming first through fourth output pins aligned in a column direction, forming the first through fourth output pins including forming a first electrical connection from the first bit circuit to the first output pin positioned adjacent to the second bit circuit, forming a second electrical connection from the second bit circuit to the second output pin positioned adjacent to the second bit circuit, forming a third electrical connection from the third bit circuit to the third output pin positioned adjacent to the fourth bit circuit, and forming a fourth electrical connection from the fourth bit circuit to the fourth output pin positioned adjacent to the fourth bit circuit. In some embodiments, forming the first through seventh power rails includes forming the first through seventh power rails in a first metal layer of the IC device, forming the plurality of metal segments includes forming a plurality of first metal segments in the first metal layer, and the first metal segments of the plurality of first metal segments are positioned in accordance with a total of three first metal tracks extending between adjacent power rails of the first through seventh power rails. In some embodiments, forming the first through fourth output pins includes forming first through fourth second metal segments in a second metal layer of the IC device. In some embodiments, constructing the plurality of transistors includes forming fifth and sixth bit circuits including thirteenth through eighteenth active areas extending along the row direction and forming seventh and eighth bit circuits including nineteenth through twenty-fourth active areas extending along the row direction, and forming the plurality of metal segments includes forming eighth through thirteenth power rails extending in the row direction, wherein the seventh power rail further overlies each of the fifth and sixth bit circuits, the eighth and ninth power rails overlie each of the fifth and sixth bit circuits, the tenth power rail overlies each of the fifth through eighth bit circuits, and the eleventh through thirteenth power rails overlie each of the seventh and eighth bit circuits, and forming the first through fourth output pins includes forming a fifth output pin and a fifth electrical connection from the fifth bit circuit to the fifth output pin positioned adjacent to the sixth bit circuit, forming a sixth output pin and a sixth electrical connection from the sixth bit circuit to the sixth output pin positioned adjacent to the sixth bit circuit, forming a seventh output pin and a seventh electrical connection from the seventh bit circuit to the seventh output pin positioned adjacent to the eighth bit circuit, and forming an eighth output pin and an eighth electrical connection from the eighth bit circuit to the eighth output pin positioned adjacent to the eighth bit circuit. In some embodiments, constructing the plurality of transistors includes forming fifth and sixth bit circuits including the first through sixth active areas and forming seventh and eighth bit circuits including the seventh through twelfth active areas, and forming the plurality of metal segments includes forming the first through third power rails further overlying each of the fifth and sixth bit circuits, forming the fourth power rail further overlying each of the fifth through eighth bit circuits, and forming the fifth through seventh power rails further overlying each of the seventh and eighth bit circuits, and forming fifth through eighth output pins aligned in the column direction adjacent to the first through fourth output pins, forming the fifth through eighth output pins including forming a fifth output pin and a fifth electrical connection from the fifth bit circuit to the fifth output pin positioned adjacent to the sixth bit circuit, forming a sixth output pin and a sixth electrical connection from the sixth bit circuit to the sixth output pin positioned adjacent to the sixth bit circuit, forming a seventh output pin and a seventh electrical connection from the seventh bit circuit to the seventh output pin positioned adjacent to the eighth bit circuit, and forming an eighth output pin and an eighth electrical connection from the eighth bit circuit to the eighth output pin positioned adjacent to the eighth bit circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device comprising:
first and second bit circuits adjacent to each other along a row direction;
third and fourth bit circuits adjacent to each other along the row direction; and
a first column of output pins aligned in a column direction,
wherein
the first and second bit circuits comprise:
first through fourth power rails extending in the row direction; and
first through sixth active areas extending in the row direction,
the third and fourth bit circuits comprise:
the fourth power rail and fifth through seventh power rails extending in the row direction; and
seventh through twelfth active areas extending in the row direction, and
the first column of output pins comprises:
first and second output pins adjacent to the second bit circuit and coupled to the respective first and second bit circuits; and
third and fourth output pins adjacent to the fourth bit circuit and coupled to the respective third and fourth bit circuits.

2. The IC device of claim 1, wherein
the first through seventh power rails are positioned in a first metal layer of the IC device,
each of the first through fourth bit circuits further comprises a plurality of metal segments positioned in the first metal layer, and
the metal segments of the plurality of metal segments are positioned in accordance with a total of three first metal tracks extending between adjacent power rails of the first through seventh power rails.

3. The IC device of claim 2, wherein
each of the first through fourth output pins comprises a metal segment extending in the column direction in a second metal layer of the IC device.

4. The IC device of claim 1, wherein
each of the first through fourth bit circuits is coupled to a same clock signal path.

5. The IC device of claim 1, further comprising:
fifth and sixth bit circuits adjacent to each other along the row direction; and
seventh and eighth bit circuits adjacent to each other along the row direction,
wherein
the fifth and sixth bit circuits comprise:
the seventh power rail and eighth through tenth power rails extending in the row direction; and
thirteenth through eighteenth active areas extending in the row direction,
the seventh and eighth bit circuits comprise:
the tenth power rail and eleventh through thirteenth power rails extending in the row direction; and
nineteenth through twenty-fourth active areas extending in the row direction, and
the first column of output pins further comprises:
fifth and sixth output pins adjacent to the sixth bit circuit and coupled to the respective fifth and sixth bit circuits; and
seventh and eighth output pins adjacent to the eighth bit circuit and coupled to the respective seventh and eighth bit circuits.

6. The IC device of claim 1, further comprising:
a second column of output pins adjacent to the first column of output pins;
fifth and sixth bit circuits adjacent to each other along the row direction; and
seventh and eighth bit circuits adjacent to each other along the row direction,
wherein
the fifth and sixth bit circuits comprise the first through fourth power rails and first through sixth active areas,
the seventh and eighth bit circuits comprise the fourth through seventh power rails and seventh through twelfth active areas, and
the second column of output pins comprises:
fifth and sixth output pins adjacent to the sixth bit circuit and coupled to the respective fifth and sixth bit circuits; and
seventh and eighth output pins adjacent to the eighth bit circuit and coupled to the respective seventh and eighth bit circuits.

7. The IC device of claim 1, wherein
the IC device comprises a multi-bit flip-flop circuit, and
each of the first through fourth bit circuits comprises a flip-flop bit circuit.

8. The IC device of claim 1, wherein
each of the first through fourth bit circuits comprises an input pin.

9. An integrated circuit (IC) device comprising:
a first row comprising adjacent first and second flip-flop bits;
a second row comprising adjacent third and fourth flip-flop bits; and
a first column of output pins aligned perpendicular to the first and second rows,
wherein
the first and second flip-flop bits comprise first through fourth power rails and first through sixth active areas extending along the first row,
the third and fourth flip-flop bits comprise the fourth power rail, fifth through seventh power rails, and seventh through twelfth active areas extending along the second row, and
the first column of output pins comprises:
a first output pin adjacent to the second flip-flop bit and electrically connected to the first flip-flop bit;
a second output pin adjacent to the second flip-flop bit and electrically connected to the second flip-flop bit;
a third output pin adjacent to the fourth flip-flop bit and electrically connected to the third flip-flop bit; and
a fourth output pin adjacent to the fourth flip-flop bit and electrically connected to the fourth flip-flop bit.

10. The IC device of claim 9, wherein
the first through seventh power rails are positioned in a first metal layer of the IC device,
each of the first through fourth flip-flop bits further comprises a plurality of metal segments positioned in the first metal layer, and
the metal segments of the plurality of metal segments are positioned in accordance with a total of three first metal tracks extending between adjacent power rails of the first through seventh power rails.

11. The IC device of claim 10, wherein
each of the first through fourth output pins comprises a metal segment extending perpendicular to the first and second rows in a second metal layer of the IC device.

12. The IC device of claim 9, further comprising:
a pair of clock paths electrically connected to each of the first through fourth bits.

13. The IC device of claim 9, further comprising:
a third row comprising adjacent fifth and sixth flip-flop bits; and
a fourth row comprising adjacent seventh and eighth flip-flop bits,
wherein
the fifth and sixth flip-flop bits comprise the seventh power rail, eighth through tenth power rails, and thirteenth through eighteenth active areas extending along the third row,
the seventh and eighth flip-flop bits comprise the tenth power rail, eleventh through thirteenth power rails, and nineteenth through twenty-fourth active areas extending along the fourth row, and
the first column of output pins further comprises:
a fifth output pin adjacent to the sixth flip-flop bit and electrically connected to the fifth flip-flop bit;
a sixth output pin adjacent to the sixth flip-flop bit and electrically connected to the sixth flip-flop bit;
a seventh output pin adjacent to the eighth flip-flop bit and electrically connected to the seventh flip-flop bit; and
an eighth output pin adjacent to the eighth flip-flop bit and electrically connected to the eighth flip-flop bit.

14. The IC device of claim 9, further comprising:
a second column of output pins adjacent to the first column of output pins,
wherein
the first row further comprises adjacent fifth and sixth flip-flop bits,
the second row further comprises adjacent seventh and eighth flip-flop bits,
the fifth and sixth flip-flop bits comprise the first through fourth power rails and first through sixth active areas,
the seventh and eighth flip-flop bits comprise the fourth through seventh power rails and seventh through twelfth active areas, and
the second column of output pins comprises:
a fifth output pin adjacent to the sixth flip-flop bit and electrically connected to the fifth flip-flop bit;
a sixth output pin adjacent to the sixth flip-flop bit and electrically connected to the sixth flip-flop bit;
a seventh output pin adjacent to the eighth flip-flop bit and electrically connected to the seventh flip-flop bit; and
an eighth output pin adjacent to the eighth flip-flop bit and electrically connected to the eighth flip-flop bit.

15. The IC device of claim 9, wherein
each of the first through fourth flip-flop bits comprises an input pin.

16. A method of manufacturing an integrated circuit (IC) device, the method comprising:
constructing a plurality of transistors, the constructing the plurality of transistors comprising:
forming first and second bit circuits comprising first through sixth active areas extending along a row direction; and
forming third and fourth bit circuits comprising seventh through twelfth active areas extending along the row direction; and
forming a plurality of metal segments, the forming the plurality of metal segments comprising:
forming first through seventh power rails extending in the row direction, wherein
the first through third power rails overlie each of the first and second bit circuits,
the fourth power rail overlies each of the first through fourth bit circuits, and
the fifth through seventh power rails overlie each of the third and fourth bit circuits; and
forming first through fourth output pins aligned in a column direction, the forming the first through fourth output pins comprising:
forming a first electrical connection from the first bit circuit to the first output pin positioned adjacent to the second bit circuit;
forming a second electrical connection from the second bit circuit to the second output pin positioned adjacent to the second bit circuit;
forming a third electrical connection from the third bit circuit to the third output pin positioned adjacent to the fourth bit circuit; and
forming a fourth electrical connection from the fourth bit circuit to the fourth output pin positioned adjacent to the fourth bit circuit.

17. The method of claim 16, wherein
the forming the first through seventh power rails comprises forming the first through seventh power rails in a first metal layer of the IC device,
the forming the plurality of metal segments further comprises forming a plurality of first metal segments in the first metal layer, and
the first metal segments of the plurality of first metal segments are positioned in accordance with a total of three first metal tracks extending between adjacent power rails of the first through seventh power rails.

18. The method of claim 17, wherein
the forming the first through fourth output pins comprises forming first through fourth second metal segments in a second metal layer of the IC device.

19. The method of claim 16, wherein
the constructing the plurality of transistors further comprises:
forming fifth and sixth bit circuits comprising thirteenth through eighteenth active areas extending along the row direction; and
forming seventh and eighth bit circuits comprising nineteenth through twenty-fourth active areas extending along the row direction; and
the forming the plurality of metal segments further comprises:
forming eighth through thirteenth power rails extending in the row direction, wherein
the seventh power rail further overlies each of the fifth and sixth bit circuits,
the eighth and ninth power rails overlie each of the fifth and sixth bit circuits,
the tenth power rail overlies each of the fifth through eighth bit circuits, and
the eleventh through thirteenth power rails overlie each of the seventh and eighth bit circuits; and
the forming the first through fourth output pins further comprises:
forming a fifth output pin and a fifth electrical connection from the fifth bit circuit to the fifth output pin positioned adjacent to the sixth bit circuit;
forming a sixth output pin and a sixth electrical connection from the sixth bit circuit to the sixth output pin positioned adjacent to the sixth bit circuit;
forming a seventh output pin and a seventh electrical connection from the seventh bit circuit to the seventh output pin positioned adjacent to the eighth bit circuit; and
forming an eighth output pin and an eighth electrical connection from the eighth bit circuit to the eighth output pin positioned adjacent to the eighth bit circuit.

20. The method of claim 16, wherein
the constructing the plurality of transistors further comprises:
forming fifth and sixth bit circuits comprising the first through sixth active areas; and
forming seventh and eighth bit circuits comprising the seventh through twelfth active areas; and
the forming the plurality of metal segments further comprises:
forming the first through third power rails further overlying each of the fifth and sixth bit circuits,
forming the fourth power rail further overlying each of the fifth through eighth bit circuits, and
forming the fifth through seventh power rails further overlying each of the seventh and eighth bit circuits; and
forming fifth through eighth output pins aligned in the column direction adjacent to the first through fourth output pins, the forming the fifth through eighth output pins comprising:
forming a fifth output pin and a fifth electrical connection from the fifth bit circuit to the fifth output pin positioned adjacent to the sixth bit circuit;
forming a sixth output pin and a sixth electrical connection from the sixth bit circuit to the sixth output pin positioned adjacent to the sixth bit circuit;
forming a seventh output pin and a seventh electrical connection from the seventh bit circuit to the seventh output pin positioned adjacent to the eighth bit circuit; and
forming an eighth output pin and an eighth electrical connection from the eighth bit circuit to the eighth output pin positioned adjacent to the eighth bit circuit.
